(19) United States
(12) Patent Application Publication
(10) Pub. No.: US 2022/0057680 A1
(43) Pub. Date: Feb. 24, 2022

(54) LIQUID CRYSTAL DISPLAY PANEL AND TESTING METHOD THEREOF

(71) Applicant: SHENZHEN CHINA STAR OPTOELECTRONICS SEMICONDUCTOR DISPLAY TECHNOLOGY CO., LTD., Shenzhen (CN)

(72) Inventor: Jianxin Liu, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 17/251,714

(22) PCT Filed: Mar. 31, 2020
(86) PCT No.: PCT/CN2020/082406

§ 371 Date: Dec. 11, 2020

(30) Foreign Application Priority Data
Jan. 14, 2020 (CN) 202010038113.6

(51) Int. Cl. G02F 1/1362; H05K 1/18

(52) U.S. Cl. CPC G02F 1/136254; H05K 2201/10136; H05K 1/189; G02F 1/136286

(57) ABSTRACT

A liquid crystal display panel and a testing method thereof are provided. A circuit is shared for a box test and an array test, and a plurality of test lines and a plurality of test pads are not needed to be disposed in the liquid crystal display panel separately for the box test and the array test, that is, areas for disposing the plurality of test lines and the plurality of test pads are not needed to be reserved for the box test and the array test, which can increase a cuttable size of the liquid crystal display panel and increase a number of extractions from the liquid crystal display panel.

### BACKGROUND

### Field of Invention

The present disclosure relates to a field of display technology, and more particularly, to a liquid crystal display panel and a testing method.

### Description of the Prior Art

Liquid crystal displays (LCDs) have advantages of low power consumption and are still current mainstream display devices. In order to improve production yield during a production process, the LCDs need to do an array test after preparation of an array substrate and do a cell test (also as known liquid crystal display panel test) after preparation of a cell process. Based on the array test and the cell test, as shown in FIG. 1, before a cutting process during a production process of the LCDs 10, the LCDs 10 are disposed on a substrate 11 in an array. Each of the LCDs 10 is not only provided with a plurality of test pads 121 and a plurality of test lines 122 for an array test on an outside thereof, but are also provided with a plurality of test pads 131 and a plurality of test lines 132 for the cell test in a non-display area thereof. After the array test, the plurality of test pads 121 and part of the plurality of test lines 122 are cut and removed, and the plurality of test pads 131 and the plurality of test lines 132 for the cell test are preserved as interior structures because the plurality of test pads 131 and the plurality of test lines 132 for the cell test are disposed in the non-display area of each of the plurality of LCDs.

It can be seen that in the prior art, the plurality of test pads 121 and test lines 122 for the array test can occupy a part of an area of the substrate 11, and the plurality of test pads 131 and a plurality of test lines 132 also occupy another part of the substrate 11. It is necessary to reserve a separate area for test pads and test lines of these two tests, which obviously result in a smaller cuttable size (that is a size of each of LCDs after cutting) of each of the plurality of LCDs 10.

### SUMMARY

An existing circuit of an array test and a box test affect a cuttable size of a liquid crystal display panel.

The present disclosure provides a liquid crystal display panel, including: a plurality of pixel units and a driving circuit configured to drive the plurality of pixel units, and the liquid crystal display panel further including a plurality of test lines, and a plurality of test pads, wherein:

the plurality of test pads are disposed in a non-display area of the liquid crystal display panel;

each of the plurality of test lines is connected to a corresponding one of the plurality of test pads and the driving circuit;

each of the plurality of test pads is disposed to contact with a box test probe and is disposed to contact with an array test probe before cutting a plurality of liquid crystal display panels disposed in an array;

the plurality of test pads are disposed in the non-display area on a same side of the liquid crystal display panel; and

the plurality of test pads include a first test pad, a second test pad, and a third test pad, wherein the first test pad is connected to a scan line of the liquid crystal display panel by a corresponding one of the plurality of test lines, the second test pad is connected to a data line of the liquid crystal display panel through a corresponding one of the plurality of test lines, the third test pad is connected to a common electrode of the liquid crystal display panel by a corresponding one of the plurality of test lines.

The present disclosure provides a liquid crystal display panel, including a plurality of pixel units and a driving circuit configured to drive the plurality of pixel units, and the liquid crystal display panel further including a plurality of test lines, and a plurality of test pads, wherein:

the plurality of test pads are disposed in a non-display area of the liquid crystal display panel;

each of the plurality of test lines is connected to a corresponding one of the plurality of test pads and the driving circuit;

each of the plurality of test pads is disposed to contact with a box test probe and is disposed to contact with an array test probe before cutting a plurality of liquid crystal display panels disposed in an array.

The present disclosure provides a testing method of a liquid crystal display panel, including:

providing a plurality of liquid crystal display panels to be cut disposed in an array, wherein each of the plurality of liquid crystal display panels includes a plurality of test pads and a plurality of test lines both disposed in a non-display area, and each of the plurality of test lines is connected to a corresponding one of the plurality of test pads and a driving circuit configured to drive a plurality of pixel units of each of the plurality of liquid crystal display panels;

performing an array test on the connected liquid crystal display panel by the plurality of test pads and the plurality of test lines, before cutting the plurality of liquid crystal display panels disposed in the array;

performing a box test on the connected liquid crystal display panel by the plurality of test pads and the plurality of test lines, after cutting the plurality of liquid crystal display panels disposed in the array.

The liquid crystal display panel and the testing method thereof are provided. The disclosure is designed to share a circuit for the box test and the array test, and the plurality of test lines and the plurality of test pads are not need to be disposed in the liquid crystal display panel separately for the box test and the array test, that is, areas for disposing the plurality of test line and the plurality of test pads do not needed to be reserved for the box test and the array test, which can increase a cuttable size of the liquid crystal display panel and increase a number of extractions of the liquid crystal display panel.

### BRIEF DESCRIPTION OF DRAWINGS

In order to more clearly illustrate the technical solution in the present disclosure or in the prior art, the following will illustrate the figures used for describing the embodiments or the prior art. It is obvious that the following figures are only some embodiments of the present disclosure. For a person of ordinary skill in the art, without creative effort, other figures can also be obtained according to these figures.

FIG. 1 is a structural schematic diagram of a plurality of existing liquid crystal displays disposed in an array.

FIG. 2 is a cross-sectional structural diagram of a liquid crystal display panel according to an embodiment of the present disclosure.

FIG. 3 is a structural schematic diagram of a pixel of a liquid crystal display panel shown in FIG. 2 according to an embodiment of the present disclosure.

FIG. 4 is an equivalent structural schematic diagram of a partial circuit of a liquid crystal display panel before being cut according to an embodiment of the present disclosure.

FIG. 5 is an equivalent structural diagram of a partial circuit of a liquid crystal display panel after cutting according to an embodiment of the present disclosure as shown in FIG. 4.

FIG. 6 is a schematic diagram of a testing method of a liquid crystal display panel according to an embodiment of the present disclosure.

### DETAILED DESCRIPTION OF PREFERRED EMBODIMENTS

The detailed description set forth below is intended as a description of the subject technology with reference to the appended figures and embodiments. It is understood that the embodiments described herein include merely some parts of the embodiments of the present disclosure, but do not include all the embodiments. Based on the embodiments of the present disclosure, all other embodiments that those skilled in the art may derive from these embodiments are within the scope of the present disclosure.

FIG. 2 is a cross-sectional structural diagram of a liquid crystal display panel according to an embodiment of the present disclosure. Please refer to FIG. 2, a liquid crystal display panel 20 includes a color filter substrate (CF) 22 and an array substrate (known as a thin-film transistor substrate, abbreviated as TFT substrate) 21 disposed at a relatively interval, and a plurality of liquid crystal molecules 23 filled between two substrate. The plurality of liquid crystal molecules 23 are filled in a liquid crystal cell formed by superimposing the array substrate 21 and the color filter substrate 22.

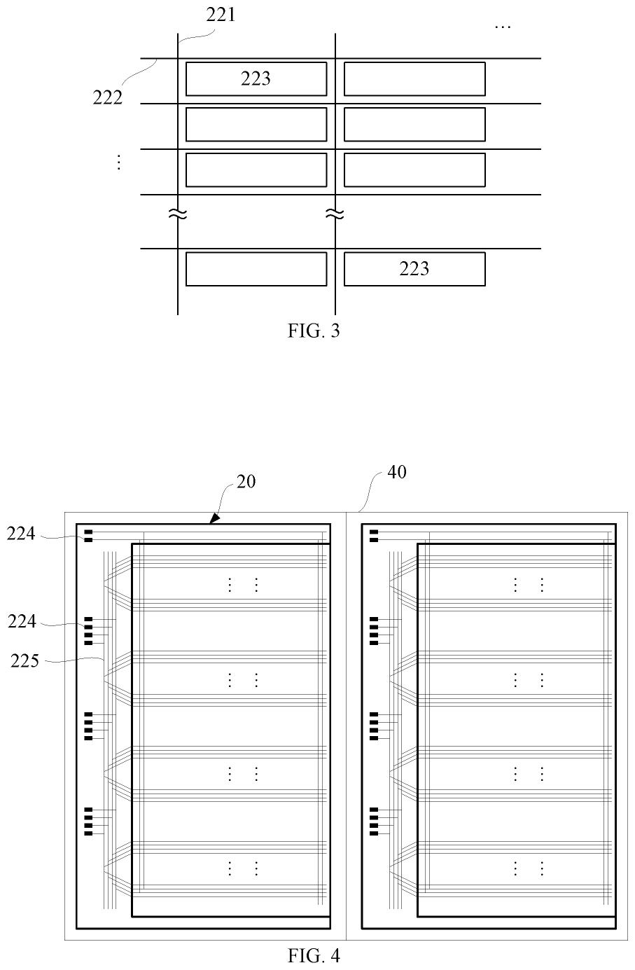

Please refer to FIG. 2 and FIG. 3, the array substrate 21 includes a plurality of data lines 221 extending along a column direction, a plurality of scan lines 222 extending along a row direction, and a plurality of pixel units 223 disposed in the array and defined by the plurality of scan lines and the plurality of data lines. Each of the plurality of pixel units 223 can be connected to a corresponding data line 221 and a corresponding scan line 222. Each of the plurality of scan lines 222 is configured to provide a scan voltage to each of the plurality of pixel units. Each of the plurality of data lines 221 is configured to provide a gray scale voltage to each of the plurality of pixel units.

According to a display principle of the liquid crystal display panel 20, the scan lines 222, the data lines 221, and other structures (such as lines connected to a common electrode of the liquid crystal display panel 20) together constitute a driving circuit of the pixel units 223. The thin-film transistors of the pixel unit 223 in a same row are turned on at the same time by inputting a scan voltage through the scan line 222, and a voltage difference is generated between a pixel electrode of the pixel unit 223 and the common electrode of the liquid crystal display panel 20. An electrode field generated by the voltage difference controls a deflection of the liquid crystal molecules 23, thereby allowing a backlight to pass through a liquid crystal layer to generate a picture, wherein the common electrode can be disposed on the color filter substrate 22.

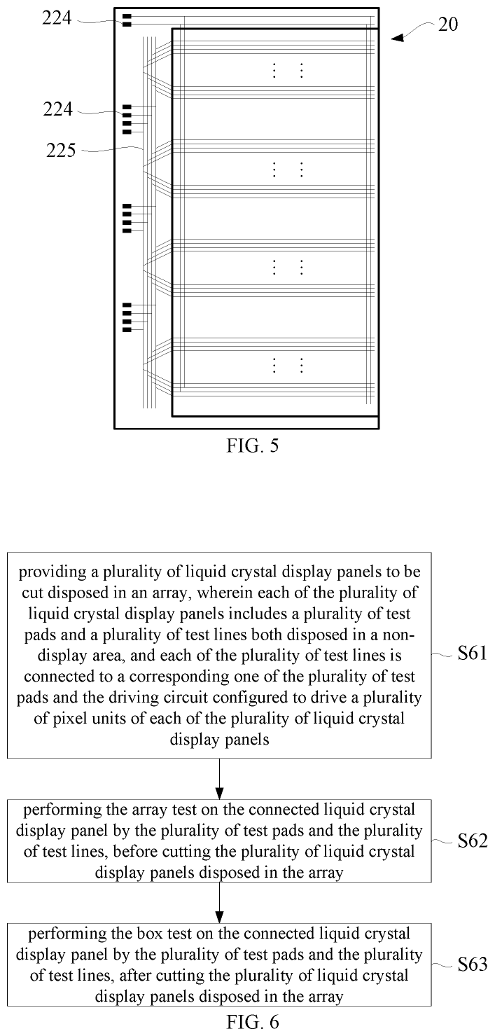

In order to improve a product yield, performing an array test and a box test on the liquid crystal display panel 20 are necessary during a production process. Therefore, the liquid crystal display panel 20 according to the embodiment of the present disclosure needs to reserve a circuit for the array test and the box test. Wherein the array test is performed after the array substrate 21 are prepared, and the box test is performed after the array substrate 21 and the color filter substrate 22 are prepared after a box process. A test circuit is described below in conjunction with FIG. 4 and FIG. 5.

Please refer to FIG. 4 and FIG. 5, a manufacturing process of the liquid crystal display panel 20 includes a cutting process. That is, a plurality of liquid crystal display panels 20 disposed on the substrate 40 in the array are cut to extract each of the plurality of liquid crystal display panels 20, and each of the plurality of liquid crystal display panels 20 has a same structure. It can be understood that only two of the plurality of liquid crystal display panels 20 are shown in FIG. 4. For illustrative purposes, a number of the plurality of liquid crystal display panels 20 disposed on the substrate 40 in the array depends on a need in an actual application scenario.

Take any one of the plurality of liquid crystal display panels 20 as an example, as shown in FIG. 5, the liquid crystal display panel 20 includes a plurality of test lines 225, and a plurality of test pads 224. The plurality of test pads 224 can be spaced apart from each other and are disposed in a non-display area (also known as line area) on a same side of the liquid crystal display panel 20, as shown in a left non-display area in FIG. 4. The plurality of test pads 224 can be divided into three types according to different functions, namely a first test pad, a second test pad, a third test pad. The first test pad is connected to one of the plurality of scan lines 222 of the liquid crystal display panel 20 by a corresponding one of the plurality of test lines 225. The second test pad is connected to one of the plurality of data lines 221 of the liquid crystal display panel 20 through a corresponding one of the plurality of test lines 225. The third test pad is connected to the common electrode of the liquid crystal display panel 20 by a corresponding one of the plurality of test lines 225.

Each of the plurality of test lines 225 is connected to a corresponding one of the plurality of test pads 224 and a corresponding part of the driving circuit of the liquid crystal display panel 20, and an arrangement of each of the plurality of test lines 225 needs to be determined according to a position of the corresponding one of the plurality of test pads 224. As shown in FIG. 4, for the first test pad disposed in the non-display are on a left side of the liquid crystal display 20, each of the plurality of test lines 225 includes a horizontal line and a vertical line. Two ends of the horizontal line are connected to the vertical line and the test pad 224 separately, and the vertical line is connected to the scan line 222. The test line 225 connected to the second test pad can be disposed on an upper portion of the non-display area of the liquid crystal display panel 20.

In the array test stage, a first part of the plurality of test pads 224 are in contact with a plurality of probes to perform an electric test on the array substrate 21. After recognizing a location and other information about defections, identify and mark the defections, and then repair the defection. In the box test stage, each of the first part of plurality of test pads 224 is contact with a corresponding one of the plurality of probes, and each of a second part of plurality of test pads 224 is contact with a corresponding one of the plurality of probes, thereby assisting the liquid crystal display panel 20 to light up so that it can display various colors and pictures. Subsequently, human eye detection and judgment classify identified defects in order to decide whether to proceed to a next process.

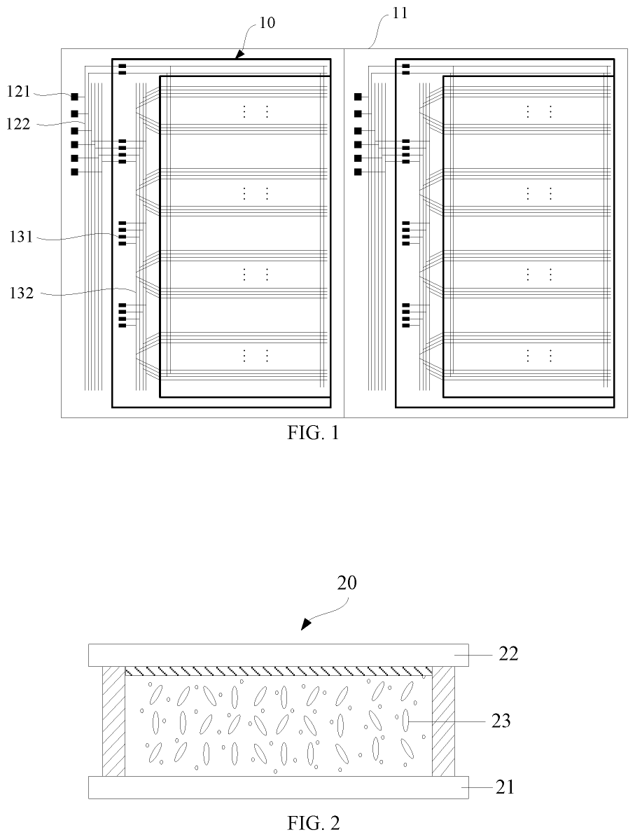

Based on the above, it can be seen that the box test and the array test of the liquid crystal display panel 20 are realized by sharing a common circuit, that is, only one set of the plurality of test lines 225 and the plurality of test pads 224, and multiplexing an original driving circuit of the liquid crystal display panel 20. The liquid crystal display panel 20 does not need to separately reserve areas for the box test and the array test to accommodate the plurality of test lines and the plurality of test pads. As shown in FIG. 1 and FIG. 4, before being cut, the liquid crystal display panel 20 does not need to separately reserve the areas for the box test and the array test to accommodate the plurality of test lines 225 and the plurality of test pads 224, and can increase a cuttable size of the liquid crystal display panel 20 (that is a size of the liquid crystal display panel 20 after being cut). A size of an effective display area of the liquid crystal display panel 20 according to an embodiment of the present disclosure is larger than a size of the effective display area of a prior art liquid crystal display panel 10.

On another hand, as shown in FIG. 1 and FIG. 4, for the substrate on which all of the plurality of liquid crystal display panels are disposed in array with same area, an extraction number of the plurality of liquid crystal display panels 20 according to an embodiment of the present disclosure, is larger than that in the prior art, that is, it is conducive to increase the extraction number of the plurality of liquid crystal display panel 20, while obtaining the plurality of the liquid crystal display panel 20 of a same cuttable size.

In view of a fact that an integrated circuit (IC) is also disposed in the non-display area of the liquid crystal display panel 20, the integrated circuit can be configured to provide a drive signal for a module test of the liquid crystal display panel 20. In view of a fact that the integrated circuit is disposed in a circuit board in the non-display area of the liquid crystal display panel 20, in order to realize a narrow bezel design of the liquid crystal display panel 20, the plurality of test pads 224 and the integrated circuit can be disposed in a same circuit board, such as flexible printed circuit (FPC).

A testing method of the liquid crystal display panel has also been provided according to an embodiment of the present disclosure. As shown in FIG. 6, the testing method includes steps of S61-S63:

S61, providing a plurality of liquid crystal display panels to be cut disposed in an array, wherein each of the plurality of liquid crystal display panels includes a plurality of test pads and a plurality of test lines both disposed in a non-display area, and each of the plurality of test lines is connected to a corresponding one of the plurality of test pads and the driving circuit configured to drive a plurality of pixel units of each of the plurality of liquid crystal display panels.

S62, performing the array test on the connected liquid crystal display panel by the plurality of test pads and the plurality of test lines, before cutting the plurality of liquid crystal display panels disposed in the array.

S63, performing the box test on the connected liquid crystal display panel by the plurality of test pads and the plurality of test lines, after cutting the plurality of liquid crystal display panels disposed in the array.

Each of the plurality of liquid crystal display panels based on the testing method have the same structure as the liquid crystal display panel 20 according to the embodiment of the present disclosure. Therefore, the test method also has a same beneficial effect.

Although the disclosure has been shown and described with respect to one or more implementations, equivalent alterations and modifications will occur to others skilled in the art based upon a reading and understanding of this specification and the annexed drawings. The disclosure includes all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed configuration which performs the function in the herein illustrated exemplary implementations of the disclosure.

It is understood that the descriptions above are only embodiments of the present disclosure. It is not intended to limit the scope of the present disclosure. Any equivalent transformation in structure and/or in scheme referring to the instruction and the accompanying drawings of the present disclosure, and direct or indirect application in other related technical field, are included within the scope of the present disclosure.

In addition, in the descriptions according to an embodiment of the present disclosure, it should be understood that orientation or positional relationship indicated by terms “center”, “longitudinal”, “transverse”, “length”, “width”, “thickness”, “upper”, “lower”, “front”, “rear”, “left”, “right”, “vertical”, “horizontal”, “top”, “bottom”, “inner”, “outer”, etc. Is based on orientation or positional relationship of drawings. It is only for a convenience of describing the present disclosure and simplifying the description, rather than indicating or implying that devices or elements referred to must have a specific orientation, and be constructed and operated in a specific orientation. Therefore, it cannot be understood as a limitation to the present disclosure. In addition, the present disclosure can use same or different reference signs to identify structural elements with same or similar characteristics. In addition, terms “first” and “second” are configured to describe purposes only, and cannot be understood as indicating or implying relative importance or implicitly indicating the number of technical features indicated. Thus, features defined as “first” and “second” can explicitly or implicitly include one or more features. In the description of the present disclosure, a meaning of “plurality” is two or more, unless otherwise specifically limited.

According to an embodiment of the present disclosure, term “exemplary” is configured to mean “used as an example, illustration, or illustration”. Any embodiment described as “exemplary” in the present disclosure is not necessarily to be construed as more preferred or advantageous than other embodiments. In order to enable any person skilled in the art to implement and use the present disclosure, the above description is given in the present disclosure. In the above description, various details are listed for a purpose of explanation. It should be understood that those of ordinary skill in the art can recognize that the present disclosure can be implemented without using these specific details. In other embodiments, well-known structures and processes will not be elaborated in detail in order to avoid unnecessary details that obscure the description of the present application. Therefore, the present disclosure is not intended to be limited to the illustrated embodiments, but is consistent with a widest scope consistent with the principles and features disclosed in the present disclosure.

1. A liquid crystal display panel, comprising:
a plurality of pixel units and a driving circuit configured to drive the plurality of pixel units, and the liquid crystal display panel further comprising a plurality of test lines, and a plurality of test pads, wherein:
the plurality of test pads are disposed in a non-display area of the liquid crystal display panel;
each of the plurality of test lines is connected to a corresponding one of the plurality of test pads and the driving circuit;
each of the plurality of test pads is disposed to contact with a box test probe and is disposed to contact with an array test probe before cutting a plurality of liquid crystal display panels disposed in an array;
the plurality of test pads are disposed in the non-display area on a same side of the liquid crystal display panel; and
the plurality of test pads comprise a first test pad, a second test pad, and a third test pad, wherein the first test pad is connected to a scan line of the liquid crystal display panel by a corresponding one of the plurality of test lines, the second test pad is connected to a data line of the liquid crystal display panel through a corresponding one of the plurality of test lines, the third test pad is connected to a common electrode of the liquid crystal display panel by a corresponding one of the plurality of test lines.

2. The liquid crystal display panel as claimed in claim 1, wherein the corresponding one of the plurality of test lines connected to the second test pad is disposed on an upper portion of the non-display area of the liquid crystal display panel, and the first test pad is disposed on a side of the non-display area of the liquid crystal display panel.

3. The liquid crystal display panel as claimed in claim 2, wherein the corresponding one of the plurality of test lines connected to the first test pad comprises a horizontal line and a vertical line, two ends of the horizontal line are connected to the vertical line and the first test pad separately, and the vertical line is connected to the scan line.

4. The liquid crystal display panel as claimed in claim 1, wherein the plurality of test pads are disposed in a circuit board in the non-display area of the liquid crystal display panel.

5. The liquid crystal display panel as claimed in claim 4, wherein the circuit board is a flexible print circuit.

6. The liquid crystal display panel as claimed in claim 1, wherein the common electrode is disposed on a side of the liquid crystal display panel.

7. A liquid crystal display panel, comprising a plurality of pixel units and a driving circuit configured to drive the plurality of pixel units, and the liquid crystal display panel further comprising a plurality of test lines, and a plurality of test pads, wherein:
the plurality of test pads are disposed in a non-display area of the liquid crystal display panel;
each of the plurality of test lines is connected to a corresponding one of the plurality of test pads and the driving circuit;
each of the plurality of test pads is disposed to contact with a box test probe and is disposed to contact with an array test probe before cutting a plurality of liquid crystal display panels disposed in an array.

8. The liquid crystal display panel as claimed in claim 7, wherein the plurality of test pads are disposed in the non-display area on a same side of the liquid crystal display panel.

9. The liquid crystal display panel as claimed in claim 7, wherein the plurality of test pads each comprises a first test pad, a second test pad, and a third test pad, wherein the first test pad is connected to a scan line of the liquid crystal display panel by a corresponding one of the plurality of test lines, the second test pad is connected to a data line of the liquid crystal display panel through a corresponding one of the plurality of test lines, the third test pad is connected to a common electrode of the liquid crystal display panel by a corresponding one of the plurality of test lines.

10. The liquid crystal display panel as claimed in claim 9, wherein the corresponding one of the plurality of test lines connected to the second test pad is disposed on an upper portion of the non-display area of the liquid crystal display panel, and the first test pad is disposed on a side of the non-display area of the liquid crystal display panel.

11. The liquid crystal display panel as claimed in claim 10, wherein the corresponding one of the plurality of test lines connected to the first test pad comprises a horizontal line and a vertical line, two ends of the horizontal line are connected to the vertical line and the first test pad separately, and the vertical line is connected to the scan line.

12. The liquid crystal display panel as claimed in claim 7, wherein the plurality of test pads are disposed in a circuit board in the non-display area of the liquid crystal display panel.

13. The liquid crystal display panel as claimed in claim 12, wherein the circuit board is a flexible printed circuit.

14. The liquid crystal display panel as claimed in claim 9, wherein the common electrode is disposed on a side of the liquid crystal display panel.

15. A testing method of a liquid crystal display panel, comprising:
providing a plurality of liquid crystal display panels to be cut disposed in an array, wherein each of the plurality of liquid crystal display panels comprises a plurality of test pads and a plurality of test lines both disposed in a non-display area, and each of the plurality of test lines is connected to a corresponding one of the plurality of test pads and a driving circuit configured to drive a plurality of pixel units of each of the plurality of liquid crystal display panels;
performing an array test on the connected liquid crystal display panel by the plurality of test pads and the plurality of test lines, before cutting the plurality of liquid crystal display panels disposed in the array;
performing a box test on the connected liquid crystal display panel by the plurality of test pads and the plurality of test lines, after cutting the plurality of liquid crystal display panels disposed in the array.

16. The testing method as claimed in claim 15, wherein the plurality of test pads are disposed in the non-display area on a same side of each of the plurality of liquid crystal display panels, and the plurality of test pads disposed on the same side and the plurality of test lines connected thereto are configured to perform the array test and the box test on the corresponding one of the plurality of liquid crystal display panels.

17. The testing method as claimed in claim 15, wherein each of the plurality of test pads comprises a first test pad, a second test pad, and a third test pad;
wherein the first test pad is connected to a scan line of the liquid crystal display panel by a corresponding one of the plurality of test lines;
wherein the second test pad is connected to a data line of the liquid crystal display panel by a corresponding one of the plurality of test lines;
wherein the third test pad is connected to a common electrode of the liquid crystal display panel through a corresponding one of the plurality of test lines;
wherein a test line connected to the second test pad is disposed on an upper portion of the non-display area of the liquid crystal display panel, and the first test pad is disposed on a side of the non-display area of the liquid crystal display panel.

18. The testing method as claimed in claim 17, wherein the corresponding one of the plurality of test lines connected to the first test pad comprises a horizontal line and a vertical line, two ends of the horizontal line are connected to the vertical line and the first test pad separately, and the vertical line is connected to the scan line.
